(19) United States
(12) Patent Application Publication
(10) Pub. No.: US 2024/0006468 A1
(43) Pub. Date: Jan. 4, 2024

(54) RESISTOR STRUCTURE AND METHOD FOR FABRICATING THE SAME

(71) Applicant: UNITED MICROELECTRONICS CORP., Hsin-Chu City (TW)

(72) Inventors: Kuo-Hsing Lee, Hsinchu County (TW); Chun-Hsien Lin, Tainan City (TW); Chih-Wei Yang, Tainan City (TW)

(73) Assignee: UNITED MICROELECTRONICS CORP., Hsin-Chu City (TW)

(21) Appl. No.: 17/876,467

(22) Filed: Jul. 28, 2022

(30) Foreign Application Priority Data
Jul. 1, 2022 (TW) 111124785

(51) Int. Cl. H01L 49/02; H01C 17/22

(52) U.S. Cl. CPC H01L 28/24; H01C 17/22

(57) ABSTRACT

A method for fabricating a resistor structure includes the steps of forming a buffer layer on a substrate, forming a barrier layer on the buffer layer, forming a p-type semiconductor layer on the barrier layer, patterning the p-type semiconductor layer, trimming the barrier layer along a first direction, and then forming an electrode on the barrier layer along a second direction.

### BACKGROUND OF THE INVENTION

### 1. Field of the Invention

The invention relates a resistor structure having p-type gallium nitride (pGaN).

### 2. Description of the Prior Art

High electron mobility transistor (HEMT) fabricated from GaN-based materials have various advantages in electrical, mechanical, and chemical aspects of the field. For instance, advantages including wide band gap, high break down voltage, high electron mobility, high elastic modulus, high piezoelectric and piezoresistive coefficients, and chemical inertness. All of these advantages allow GaN-based materials to be used in numerous applications including high intensity light emitting diodes (LEDs), power switching devices, regulators, battery protectors, display panel drivers, and communication devices.

### SUMMARY OF THE INVENTION

According to an embodiment of the present invention, a method for fabricating a resistor structure includes the steps of forming a buffer layer on a substrate, forming a barrier layer on the buffer layer, forming a p-type semiconductor layer on the barrier layer, patterning the p-type semiconductor layer, trimming the barrier layer along a first direction, and then forming an electrode on the barrier layer along a second direction.

According to another aspect of the present invention, a resistor structure includes a buffer layer on a substrate, a barrier layer on the buffer layer, a p-type semiconductor layer on the barrier layer, and an electrode on the barrier layer and the buffer layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-8 illustrate a method for fabricating a resistor structure according to an embodiment of the present invention.

### DETAILED DESCRIPTION

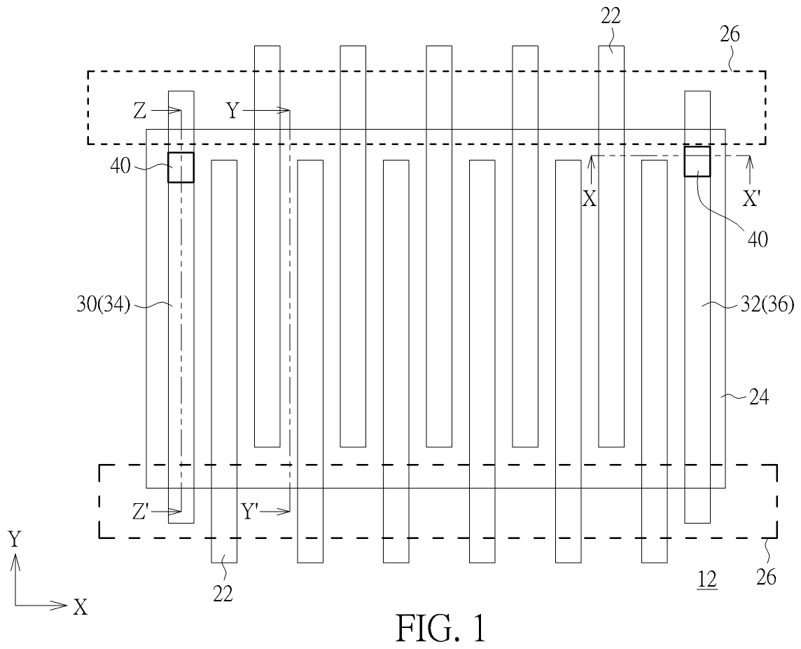

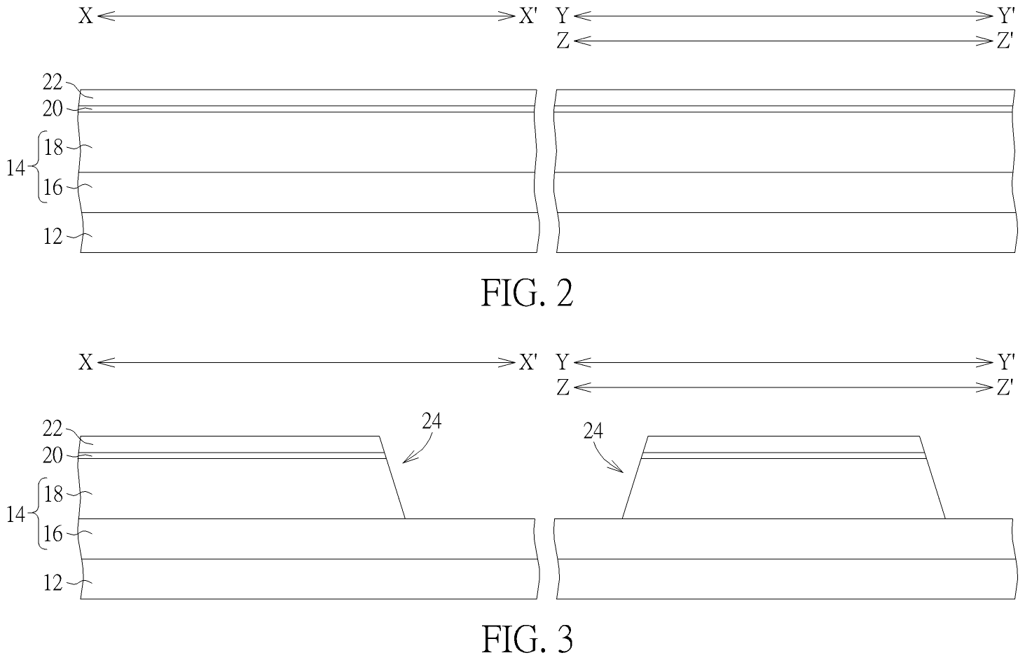

Referring to FIGS. 1-8, FIGS. 1-8 illustrate a method for fabricating a resistor structure according to an embodiment of the present invention, in which FIG. 1 illustrates a top view for fabricating the resistor structure and FIGS. 2-8 illustrate a method for fabricating the resistor structure taken along the sectional lines XX′, YY′, and ZZ′ of FIG. 1. As shown in FIGS. 1-2, a substrate 12 such as a substrate made from silicon, silicon carbide, or aluminum oxide (or also referred to as sapphire) is provided, in which the substrate 12 could be a single-layered substrate, a multi-layered substrate, gradient substrate, or combination thereof. According to other embodiment of the present invention, the substrate 12 could also include a silicon-on-insulator (SOI) substrate.

Next, a selective nucleation layer (not shown) and a buffer layer 14 are formed on the substrate 12. Preferably, the buffer layer 14 could include a bottom portion or buffer layer 16 which will not be patterned into a mesa isolation in the later process and a top portion or buffer layer 18 which will be patterned into a mesa isolation in the later process. According to an embodiment of the present invention, the nucleation layer preferably includes aluminum nitride (AlN) and the buffer layer 14 is preferably made of III-V semiconductors such as gallium nitride (GaN), a thickness of the bottom portion or buffer layer 16 is between 0.5-10 microns, and a thickness of the top portion or buffer layer 18 is between 10-270 microns. According to an embodiment of the present invention, the formation of the buffer layer 14 on the substrate 12 could be accomplished by a molecular-beam epitaxy (MBE) process, a metal organic chemical vapor deposition (MOCVD) process, a chemical vapor deposition (CVD) process, a hydride vapor phase epitaxy (HVPE) process, or combination thereof.

Next, a selective unintentionally doped (UID) buffer layer (not shown) could be formed on the surface of the buffer layer 18. In this embodiment, the UID buffer layer could be made of III-V semiconductors such as gallium nitride (GaN) or more specifically unintentionally doped GaN. According to an embodiment of the present invention, the formation of the UID buffer layer on the buffer layer 18 could be accomplished by a molecular-beam epitaxy (MBE) process, a metal organic chemical vapor deposition (MOCVD) process, a chemical vapor deposition (CVD) process, a hydride vapor phase epitaxy (HVPE) process, or combination thereof.

Next, a barrier layer 20 is formed on the surface of the UID buffer layer or buffer layer 18. In this embodiment, the barrier layer 20 is preferably made of III-V semiconductor such as n-type or n-graded aluminum gallium nitride (AlₓGa₁₋ₓN), in which 0<x<1, the barrier layer 20 preferably includes an epitaxial layer formed through epitaxial growth process, and the barrier layer 20 could include dopants such as silicon or germanium. Similar to the buffer layer 14, the formation of the barrier layer 20 on the buffer layer 18 could be accomplished by a molecular-beam epitaxy (MBE) process, a metal organic chemical vapor deposition (MOCVD) process, a chemical vapor deposition (CVD) process, a hydride vapor phase epitaxy (HVPE) process, or combination thereof.

Next, a p-type semiconductor layer 22 is formed on the barrier layer 20, in which the thickness of the p-type semiconductor layer 22 is between 80-120 nm or most preferably at 100 nm. In this embodiment, the p-type semiconductor layer 22 preferably is a III-V compound layer including p-type GaN (p-GaN) and the formation of the p-type semiconductor layer 22 on the surface of the barrier layer 20 could be accomplished by a molecular-beam epitaxy (MBE) process, a metal organic chemical vapor deposition (MOCVD) process, a chemical vapor deposition (CVD) process, a hydride vapor phase epitaxy (HVPE) process, or combination thereof.

Next, as shown in FIG. 3, a mesa isolation process is conducted to form a mesa isolation 24 so that devices could be isolated to operate independently without affecting each other. In this embodiment, the MESA isolation process could be accomplished by conducting a photo-etching process to remove part of p-type semiconductor layer 22, part of the barrier layer 20, and part of the buffer layer 18 to expose the top surface of the buffer layer 16, in which the sidewalls of the patterned p-type semiconductor layer 22, the patterned barrier layer 20, and the patterned buffer layer 18 are patterned to form inclined sidewalls that are aligned.

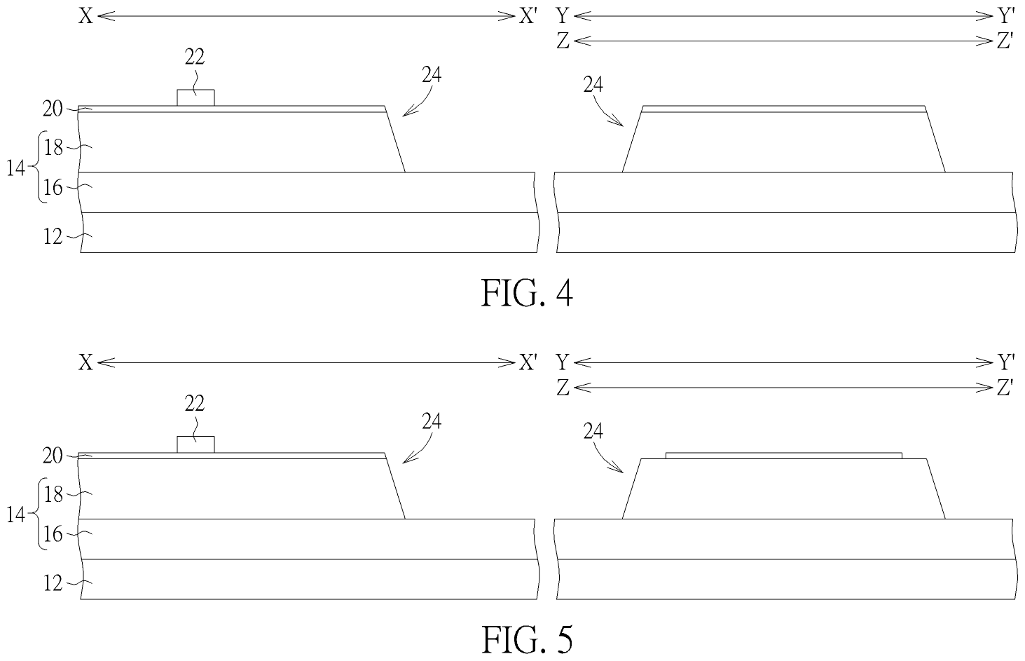

Next, as shown in FIG. 4, a photo-etching process is conducted by forming a patterned mask (not shown) on the p-type semiconductor layer 22, using the patterned mask as mask to remove part of the p-type semiconductor layer 22 through etching to form a patterned p-type semiconductor layer 22 on the barrier layer 20. It should be noted that the patterned p-type semiconductor layer 22 at this stage now becomes the rectangular and elongated stripe-shaped p-type semiconductor layer 22 extending along Y-direction as shown in FIG. 1.

Next, as shown in FIG. 5, a trimming process is conducted to remove part of the barrier layer 20. Specifically, the trimming process conducted at this stage includes conducting another photo-etching process by trimming or removing part of the barrier layer 20 along a first direction. As shown in the top view of FIG. 1 and cross-section view taken along the sectional lines YY′ and ZZ′ on right side of FIG. 5, the trimming process is accomplished by removing part of the barrier layer 20 through the opening 26 along the first direction such as the X-direction so that the width of the barrier layer 20 is slightly less than the width of the buffer layer 18 underneath. Nevertheless, the width of the barrier layer 20 taken along the direction of sectional line XX′ shown on the left side does not change.

In this embodiment, the width difference between one side such as left sidewall of the remaining barrier layer 20 and the sidewall of the buffer layer 18 underneath is approximately equal to 0.5% to 1% of the remaining overall width of the barrier layer 20. According to an embodiment of the present invention, the width difference between one side such as left side of the remaining barrier layer 20 and the left sidewall of the buffer layer 18 is about 50 nm while the overall width of the remaining barrier layer 20 is approximately 9 microns, but not limited thereto.

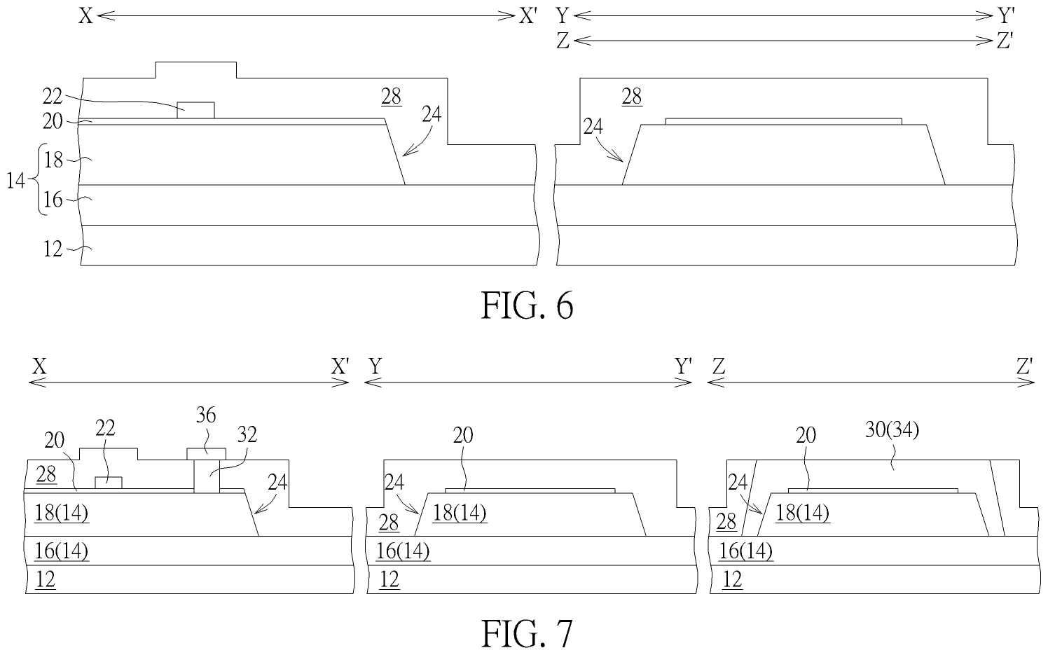

Next, as shown in FIG. 6, a passivation layer 28 is conformally formed on the buffer layer 18, the barrier layer 20, and the p-type semiconductor layer 22 to cover the top surface and sidewalls of the mesa isolation 24. In this embodiment, the passivation layer 28 preferably includes but not limited to for example silicon nitride and the thickness of the passivation layer 28 is between 100-200 nm, but not limited thereto.

Next, as shown in FIG. 7, one or more photo-etching process is conducted to remove part of the passivation layer 28 and part of the barrier layer 20 to form a plurality of openings (not shown), conductive materials are formed on the passivation layer 28 and into the openings, and one or more pattern transfer process is conducted to remove part of the conductive materials for forming patterned metal wires serving as source electrode 30 and drain electrode 32, in which the conductive material disposed above the source electrode 30 and extended to the adjacent passivation layer 28 surface is serving as a source electrode extension 34 while the conductive material disposed on the drain electrode 32 and extended to the adjacent passivation layer 28 is serving as a drain electrode extension 36. As shown in FIG. 1, both the source electrode 30 and the drain electrode 32 are extending along a second direction such as Y-direction on the buffer layer 18 adjacent to two sides of p-type semiconductor layer 22.

In this embodiment, the source electrode 30 and the drain electrode 32 are preferably made of ohmic contact metals. According to an embodiment of the present invention, each of the source electrode 30 and drain electrode 32 could include gold (Au), Silver (Ag), platinum (Pt), titanium (Ti), aluminum (Al), tungsten (W), palladium (Pd), or combination thereof. Preferably, it would be desirable to conduct an electroplating process, sputtering process, resistance heating evaporation process, electron beam evaporation process, physical vapor deposition (PVD) process, chemical vapor deposition (CVD) process, or combination thereof to form electrode materials in the aforementioned openings, and then pattern the electrode materials through one or more etching processes to form the source electrode 30 and the drain electrode 32. This completes the fabrication of a HEMT according to an embodiment of the present invention.

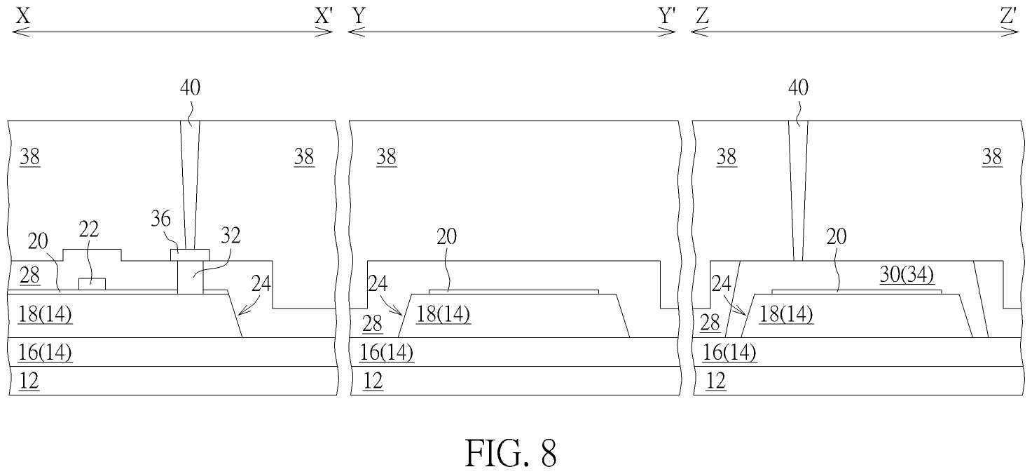

Next, as shown in FIG. 8, an interlayer dielectric (ILD) layer 38 is formed on the passivation layer 28, and a photo-etching process is conducted by using a patterned mask (not shown) as mask to remove part of the ILD layer 38 for forming contact holes (not shown) exposing the source electrode 30 and drain electrode 34. Next, conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact holes, and a planarizing process such as chemical mechanical polishing (CMP) is conducted to remove part of aforementioned barrier layer and metal layer for forming contact plugs 40 electrically connecting the source electrode 30 and drain electrode 32. This completes the fabrication of a resistor structure according to an embodiment of the present invention.

Referring to FIGS. 1 and 8, FIGS. 1 and 8 illustrate a resistor structure or resistor pattern having p-type semiconductor layer such as pGaN according to an embodiment of the present invention. As shown in FIGS. 1 and 8, the resistor structure includes a buffer layer 14 disposed on the substrate 12, a barrier layer 20 disposed on the buffer layer 14, a p-type semiconductor layer 22 disposed on the barrier layer 20, at least an electrode such as a source electrode 30 and/or drain electrode 32 disposed on the barrier layer 20 and buffer layer 18, and contact plugs 40 disposed directly on the source electrode 30 and the drain electrode 32.

It should be noted that since part of the barrier layer 20 disposed on the edge of the top surface buffer layer 18 or mesa isolation 24 has already been removed during the aforementioned trimming process, the source electrode 30 if viewed from the sectional line ZZ′ perspective would be disposed on the barrier layer 20 and buffer layer 18 while contacting the top surface of the barrier layer 20, sidewalls of the barrier layer 20, top surface of the buffer layer 18, sidewalls of the buffer layer 18, and top surface of the buffer layer 16. Preferably, the source electrode 30 and/or the drain electrode 32 include a reverse U-shape cross-section.

It should also be noted that the p-type semiconductor layer 22, the source electrode 30, and the drain electrode 32 together constitute a resistor structure and the source electrode 30 and the drain electrode 32 are connected to external circuits through the contact plugs 40. In contrast to conventional HEMT devices having gate electrode disposed directly on the p-type semiconductor layer 22, no gate electrode is formed on the p-type semiconductor layer 22 in this embodiment.

Overall, the present invention provides a method for fabricating a resistor structure having p-type semiconductor, which first forms a p-type semiconductor layer on the barrier, patterns the p-type semiconductor layer, performs a trimming process to remove part of the barrier layer on the edge of the buffer layer, and then forms a source electrode and drain electrode on the barrier layer and the buffer layer. Since the edge of the barrier layer is trimmed so that the overall width of barrier layer becomes slightly less than the width of the buffer layer underneath, the source electrode and the drain electrode if viewed from a cross-section perspective would be disposed on the barrier layer and the buffer layer while contacting the top surface of the barrier layer, sidewalls of the barrier layer, top surface of the buffer layer, and sidewalls of the buffer layer at the same time. By using the aforementioned approach to trim the barrier layer, current leakage in the resistor structure could be improved significantly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a resistor structure, comprising:
forming a buffer layer on a substrate;
forming a barrier layer on the buffer layer;
forming a p-type semiconductor layer on the barrier layer;
patterning the p-type semiconductor layer;
trimming the barrier layer; and
forming an electrode on the barrier layer.

2. The method of claim 1, further comprising:
trimming the barrier layer along a first direction; and
forming the electrode on the barrier layer along a second direction.

3. The method of claim 2, wherein the first direction is orthogonal to the second direction.

4. The method of claim 1, wherein a width of the barrier layer is less than a width of the buffer layer.

5. The method of claim 1, wherein the electrode comprises a source electrode.

6. The method of claim 1, further comprising forming the electrode on a top surface and sidewalls of the barrier layer.

7. The method of claim 1, wherein the electrode comprises a reverse U-shape.

8. The method of claim 1, wherein the buffer layer comprises gallium nitride (GaN).

9. The method of claim 1, wherein the barrier layer comprise AlₓGa₁₋ₓN.

10. The method of claim 1, wherein the p-type semiconductor layer comprises p-type gallium nitride (pGaN).

11. A resistor structure, comprising:
a buffer layer on a substrate;
a barrier layer on the buffer layer;
a p-type semiconductor layer on the barrier layer; and
an electrode on the barrier layer and the buffer layer.

12. The resistor structure of claim 11, wherein a width of the barrier layer is less than a width of the buffer layer.

13. The resistor structure of claim 11, wherein the electrode comprises a source electrode.

14. The resistor structure of claim 11, further comprising forming the electrode on a top surface and sidewalls of the barrier layer.

15. The resistor structure of claim 11, wherein the electrode comprises a reverse U-shape.

16. The resistor structure of claim 11, wherein the buffer layer comprises gallium nitride (GaN).

17. The resistor structure of claim 11, wherein the barrier layer comprise AlₓGa₁₋ₓN.

18. The resistor structure of claim 11, wherein the p-type semiconductor layer comprises p-type gallium nitride (pGaN).
